(19) United States
(12) Patent Application Publication
(10) Pub. No.: US 2008/0296638 A1
(43) Pub. Date: Dec. 4, 2008

(54) Semiconductor device and method of manufacturing the same

(76) Inventors: Chang-Woo Oh, Suwon-si (KR); Sung-In Hong, Seoul (KR); Dong-Gun Park, Seongnam-si (KR)

Correspondence Address: LEE & MORSE, P.C., 3141 FAIRVIEW PARK DRIVE, SUITE 500, FALLS CHURCH, VA, 22042, US

(21) Appl. No.: 12/153,673

(22) Filed: May 22, 2008

(30) Foreign Application Priority Data
May 28, 2007 (KR) 10-2007-0051243

(51) Int. Cl. H01L 49/00; H01L 21/336

(52) U.S. Cl. 257/288; 438/297; 257/E49.001; 257/E21.409

(57) ABSTRACT

A semiconductor device includes an active pattern on a substrate, the active pattern including a protrusion with a lower surface on the substrate and an upper surface opposite the lower surface, a width of the protrusion gradually decreasing from the lower surface to the upper surface, the upper surface of the protrusion being sharp and defining a first active region of the active pattern along a first direction, isolation layer patterns on the substrate in recesses at both sides of the active pattern, the isolation layer patterns exposing the first active region, a gate structure on the first active region and on the isolation layer patterns, the gate structure extending along a second direction, the first and second directions being perpendicular to each other, and source/drain regions under the first active region at both sides of the gate structure.

### BACKGROUND OF THE INVENTION

1. Field of the Invention

Example embodiments of the present invention relate to a semiconductor device and to a method of manufacturing the same. More particularly, example embodiments of the present invention relate to a semiconductor device having a fast operation speed and to a method of manufacturing the semiconductor device.

2. Description of the Related Art

As information media, e.g., computers, is becoming widespread, use of semiconductor devices may increase. Thus, the semiconductor devices may require fast operation speeds and high storage capacities in order to provide proper function. Further, methods of manufacturing semiconductor devices with improved degrees of, e.g., integration, reliability, response times, and so forth, may be required.

A conventional semiconductor device may include at least one transistor, e.g., a metal-oxide-semiconductor field-effect transistor (MOSFET), with a gate electrode to control electron flow through a channel region. Increased degree of integration of the conventional semiconductor device may require miniaturization of the transistor.

As the size of the transistor decreases, however, length, width, and thickness of the gate electrode therein may decrease. A decrease in the length of the gate electrode may cause drain-induced barrier lowering (DIBL), i.e., lowering of a threshold voltage barrier at high drain voltage. Therefore, charges may be discharged by the drain voltage rather than by the gate electrode, so that the transistor may not be able to operate as a switch. A decrease in the width of the gate electrode may reduce operating speed of the transistor and may lower a threshold voltage due to an inverse narrow width effect. In particular, the threshold voltage at an edge portion of the gate electrode along a widthwise direction may be lower than the threshold voltage at a central portion of the gate electrode. Thus, when the width of the gate electrode is reduced, the difference between the threshold voltages at the edge and central portions of the gate electrode may be increased, thereby making control of the threshold voltage more difficult. A decrease in the thickness of the gate may increase a leakage current between the gate electrode and a channel, thereby reducing reliability of the transistor.

### SUMMARY OF THE INVENTION

Embodiments of the present invention are therefore directed to a semiconductor device and to a method of manufacturing the same, which substantially overcome one or more of the disadvantages and shortcomings of the related art.

It is therefore a feature of an embodiment of the present invention to provide a semiconductor device with an active pattern structure capable of providing a high degree of integration.

It is another feature of an embodiment of the present invention to provide a semiconductor device with an active pattern structure capable of providing a fast operating speed.

It is yet another feature of an embodiment of the present invention to provide a semiconductor device with an active pattern structure capable of improving reliability.

It is still another feature of an embodiment of the present invention to provide a method of manufacturing a semiconductor device with an active pattern structure capable of providing one or more of the above features.

At least one of the above and other features and advantages of the present invention may be realized by providing a semiconductor device, including an active pattern on a substrate, the active pattern having a protrusion with a lower surface on the substrate and an upper surface opposite the lower surface, a width of the protrusion gradually decreasing from the lower surface to the upper surface, the upper surface of the protrusion being sharp and defining a first active region of the active pattern along a first direction, isolation layer patterns on the substrate in recesses at both sides of the active pattern, the isolation layer patterns exposing the first active region, a gate structure on the first active region and on the isolation layer patterns, the gate structure extending along a second direction, the first and second directions being perpendicular to each other, and source/drain regions under the first active region at both sides of the gate structure. The protrusion of the active pattern may have a triangular prism shape. The upper surface of the protrusion may be rounded. The upper surface of the protrusion may have a radius of curvature of about 1 nm to about 25 nm.

The active pattern may further include a second active region extending from both sides of the protrusion, the second active region having an upper surface substantially coplanar with an upper surface of the first active region and an upper width greater than an upper width of the first active region. The active pattern may include a plurality of protrusions parallel to each other, each protrusion including a first active region, and both ends of each first active region being connected to the second active region. The gate structure may include a gate insulation layer and a gate electrode on the gate insulation layer. A lower surface of the gate electrode over the first active region may have a sharp shape oriented toward the first active region. The lower surface of the gate electrode may be vertically higher than the first active region relative to the substrate. The gate structure may include a tunnel oxide layer, a charge storage layer pattern on the tunnel oxide layer, a dielectric layer pattern on the charge storage layer pattern, and a control gate pattern on the dielectric layer pattern. The charge storage layer pattern may include polysilicon doped with impurities. The charge storage layer pattern may include one or more of a silicon nitride, a nanocrystal, a silicon carbon, and a metal oxide having a high dielectric constant. A lower surface of the charge storage layer pattern over the first active region may have a sharp shape oriented toward the first active region. An upper surface of the charge storage layer pattern may have a sharp shape oriented toward the control gate pattern. A lower surface of the charge storage layer pattern may have a sharp shape oriented toward the first active region. The dielectric layer pattern may include one or more of a silicon oxide, a silicon nitride, and a metal oxide having a high dielectric constant.

At least one of the above and other features and advantages of the present invention may be realized by providing a method of manufacturing a semiconductor device, including forming an active pattern on a substrate, the active pattern having a protrusion with a lower surface on the substrate and an upper surface opposite the lower surface, a width of the protrusion gradually decreasing from the lower surface to the upper surface, the upper surface of the protrusion being sharp and defining a first active region of the active pattern along a first direction, forming isolation layer patterns on the substrate in recesses at both sides of the active pattern, the isolation layer patterns exposing the first active region, forming a gate structure on the first active region and on the isolation layer patterns, the gate structure extending along a second direction, the first and second directions being perpendicular to each other, and forming source/drain regions under the first active region at both sides of the gate structure.

Forming the upper surface of the protrusion may include forming a rounded upper surface. Forming the active pattern may include forming a hard mask pattern on the substrate, anisotropically etching the substrate using the hard mask pattern as an etching mask to form a preliminary protrusion with inclined side surfaces, and partially removing the inclined side surfaces of the preliminary protrusion to form a sharp upper surface in the protrusion of the active pattern. Partially removing the inclined side surfaces of the preliminary protrusion may include thermally oxidizing the side surfaces of the preliminary protrusion to form an oxide layer on the side surfaces of the preliminary protrusion, removing the oxide layer; and repeating the above at least once. The side surfaces of the preliminary protrusion may be removed by a wet etching process. Forming the hard mask pattern may include forming a mask having a first portion with a first width corresponding to the first active region and having a second portion with a second width corresponding to a second active region of the active pattern, the first portion of the hard mask pattern being connected to both ends of the first portion of the hard mask pattern, and the second width being greater than the first width.

### BRIEF DESCRIPTION OF THE DRAWINGS

The above and other features and advantages of the present invention will become more apparent to those of ordinary skill in the art by describing in detail exemplary embodiments thereof with reference to the attached drawings, in which:

FIGS. 1-2 illustrate plan views of charge distribution on circular and elliptical conductive plates, respectively;

FIG. 3 illustrates a cross-sectional view of two planar electrodes;

FIG. 4 illustrates a cross-sectional view of a planar electrode and a conical electrode;

FIG. 5 illustrates a plan view of a metal-oxide-semiconductor (MOS) transistor in accordance with an example embodiment of the present invention;

FIG. 6 illustrates a cross-sectional view along line I-I′ in FIG. 5;

FIG. 7 illustrates a perspective view of the MOS transistor in FIG. 5;

FIG. 8 illustrates an enlarged cross-sectional view of portion “VIII” in FIG. 6;

FIGS. 9-14 illustrate cross-sectional views of sequential stages in a method of manufacturing the MOS transistor in FIG. 5 in accordance with an example embodiment of the present invention;

FIGS. 15-18 illustrate cross-sectional views of sequential stages in a method of manufacturing the MOS transistor in FIG. 5 in accordance with another example embodiment of the present invention;

FIG. 19 illustrates a cross-sectional view of a MOS transistor in accordance with another embodiment of the present invention;

FIGS. 20-21 illustrate cross-sectional views of a method of manufacturing the MOS transistor in FIG. 19 in accordance with an example embodiment of the present invention;

FIG. 22 illustrates a plan view of a MOS transistor in accordance with another example embodiment of the present invention;

FIG. 23 illustrates a perspective view of a hard mask pattern for manufacturing the MOS transistor in FIG. 22 in accordance with an example embodiment of the present invention;

FIG. 24 illustrates a plan view of a MOS transistor in accordance with another example embodiment of the present invention;

FIG. 25 illustrates a cross-sectional view along line II-II′ in FIG. 24;

FIG. 26 illustrates a cross-sectional view of a MOS transistor in accordance with another example embodiment of the present invention;

FIG. 27 illustrates a cross-sectional view of a cell transistor of a non-volatile memory device in accordance with another embodiment of the present invention;

FIGS. 28-29 illustrate cross-sectional views of a method of manufacturing the non-volatile memory device in FIG. 27 in accordance with an example embodiment of the present invention;

FIG. 30 illustrates a cross-sectional view of a cell transistor of a non-volatile memory device in accordance with another example embodiment of the present invention;

FIG. 31 illustrates a scanning electron microscope (SEM) photograph of a MOS transistor manufactured according to an exemplary embodiment of the present invention;

FIG. 32 illustrates an enlarged SEM photograph of an active pattern of the MOS transistor in FIG. 31; and

FIG. 33 illustrates a graph of drain currents as a function of gate voltages in transistors manufactured according to an embodiment of the present invention.

### DETAILED DESCRIPTION OF THE INVENTION

Korean Patent Application No. 10-2007-0051243, filed on May 28, 2007, in the Korean Intellectual Property Office, and entitled: “Semiconductor Device and Method of Manufacturing the Same,” is incorporated by reference herein in its entirety.

Exemplary embodiments of the present invention will now be described more fully hereinafter with reference to the accompanying drawings, in which exemplary embodiments of the invention are illustrated. Aspects of the invention may, however, be embodied in different forms and should not be construed as limited to the embodiments set forth herein. Rather, these embodiments are provided so that this disclosure will be thorough and complete, and will fully convey the scope of the invention to those skilled in the art.

In the figures, the dimensions of elements, layers, and regions may be exaggerated for clarity of illustration. It will also be understood that when an element and/or layer is referred to as being “on” another element, layer and/or substrate, it can be directly on the other element, layer, and/or substrate, or intervening elements and/or layers may also be present. Further, it will be understood that the term “on” can indicate solely a vertical arrangement of one element and/or layer with respect to another element and/or layer, and may not indicate a vertical orientation, e.g., a horizontal orientation. In addition, it will also be understood that when an element and/or layer is referred to as being “between” two elements and/or layers, it can be the only element and/or layer between the two elements and/or layers, or one or more intervening elements and/or layers may also be present. Further, it will be understood that when an element and/or layer is referred to as being “connected to” or “coupled to” another element and/or layer, it can be directly connected or coupled to the other element and/or layer, or intervening elements and/or layers may be present. Like reference numerals refer to like elements throughout.

As used herein, the expressions “at least one,” “one or more,” and “and/or” may be open-ended expressions that may be both conjunctive and disjunctive in operation. For example, each of the expressions “at least one of A, B, and C,” “at least one of A, B, or C,” “one or more of A, B, and C,” “one or more of A, B, or C” and “A, B, and/or C” includes the following meanings: A alone; B alone; C alone; both A and B together; both A and C together; both B and C together; and all three of A, B, and C together. Further, these expressions may be open-ended, unless expressly designated to the contrary by their combination with the term “consisting of.” For example, the expression “at least one of A, B, and C” may also include an nth member, where n is greater than 3, whereas the expression “at least one selected from the group consisting of A, B, and C” does not.

It will be understood that, although the terms, e.g., first, second, third, and so forth, are used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of embodiments of the present invention.

Spatially relative terms, such as “beneath,” “below,” “lower,” “above,” “upper” and the like, are used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present invention. As used herein, the singular forms “a,” “an” and “the” are intended to include the plural forms as well, unless the context clearly indicates otherwise.

Example embodiments of the present invention are described herein with reference to cross-section illustrations that are schematic illustrations of idealized embodiments (and intermediate structures) of the present invention. As such, variations from the shapes of the illustrations as a result, for example, of manufacturing techniques and/or tolerances, are to be expected. Thus, example embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures may be schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

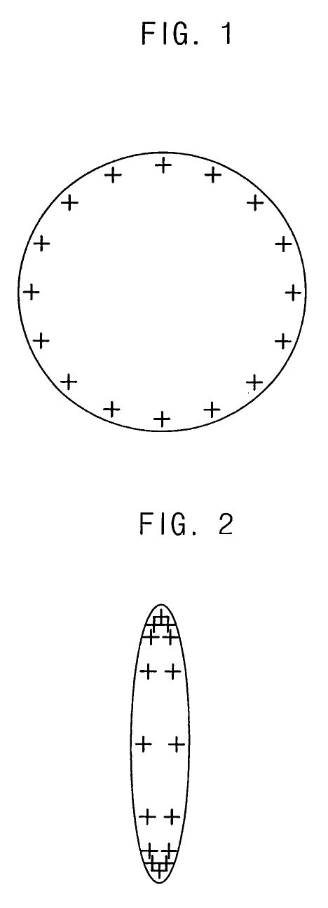

Hereinafter, control of electric fields by altering shapes of electrodes will be explained in detail with reference to FIGS. 1-4.

FIGS. 1-2 illustrate plan views of circular and elliptical conductive plates, respectively, on which charges may be distributed. Referring to FIG. 1, when a conductive plate has a circular shape, charges may be uniformly distributed on an entire surface thereof. In contrast, as illustrated in FIG. 2, when the conductive plate has an elliptical shape, charges may be non-uniformly distributed on the surface of the conductive plate, so concentration of charges in sharp edge portions of the elliptical conductive plate may be substantially higher than in other portions thereof. In other words, when substantially same voltage is applied to the entire elliptical conductive plate, a higher electric field may be formed at the sharp edge portions thereof as compared to other portions of the elliptical conductive plate. Thus, a relatively larger amount of charges may be discharged from the sharp edge portions of the elliptical conductive plate than from other portions of the elliptical conductive plate.

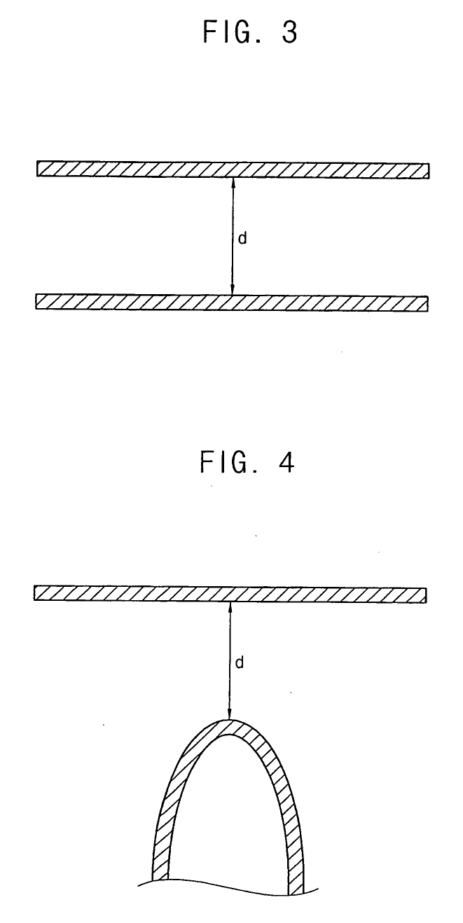

For example, FIG. 3 illustrates a cross-sectional view of two planar electrodes, and FIG. 4 illustrates a cross-sectional view of a planar electrode and of a conical electrode. Since the charge distribution may vary in accordance with the shape of the conductive plates, e.g., electrodes, intensities of the electric fields generated between the conductive plates may differ in accordance with shapes thereof. For example, as illustrated in FIG. 3, an intensity of an electric field between two planar electrodes may be represented by V/d, where V indicates a voltage and d indicates a distance between the planar electrodes. Since the electrodes in FIG. 3 may be planar, intensity of the electric field therebetween may be substantially uniform due to uniform charge distribution therebetween. When any of the planar electrodes has a sharp portion, as illustrated in FIG. 4, the electric field in the sharp portion may be distorted, and may have a substantially higher value than other portions of the electrode in accordance with a field enhancement factor β, i.e., a factor that varies in accordance with the shapes of the electrodes and may influence the intensity of the electric field. In other words, although the distance between the electrodes in FIG. 4 is substantially the same as the distance between the electrodes in FIG. 3, the intensity of the electric field between the electrodes in FIG. 4 may be substantially higher than the intensity of the electric field between the electrodes in FIG. 3 due to the conical electrode in FIG. 4. Therefore, when applying substantially same voltage to electrodes, the intensity of the electric field therebetween may be increased or decreased by changing the shapes of the electrodes. As a result, electric fields applied to elements in semiconductor devices may be adjusted by altering shapes of active region.

Hereinafter, example embodiments of the present invention may be illustrated in detail with reference to the drawings.

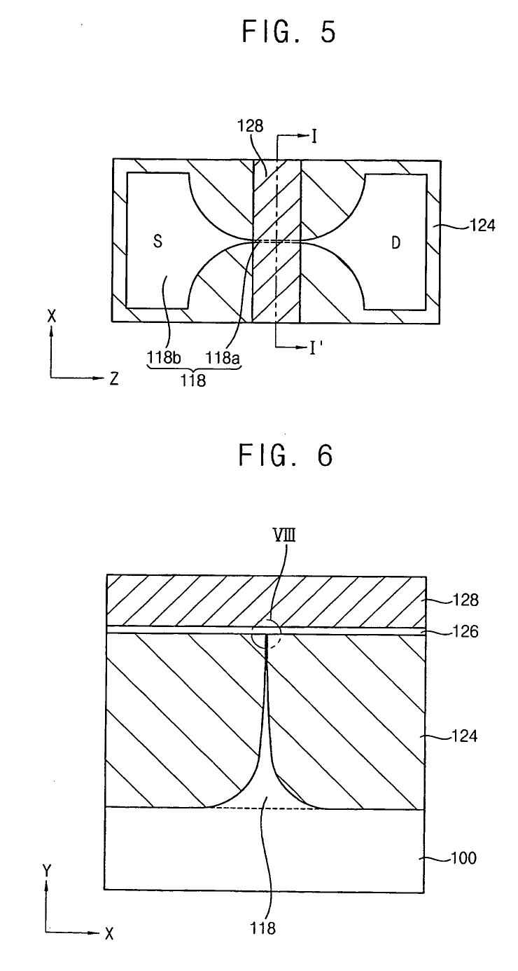

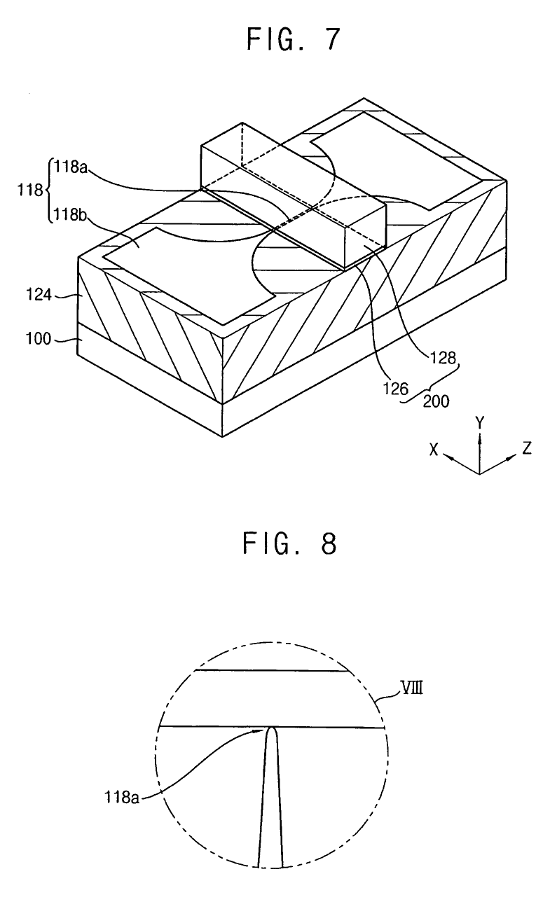

FIG. 5 illustrates a plan view of a metal-oxide-semiconductor (MOS) transistor in accordance with an example embodiment of the present invention, FIG. 6 illustrates a cross-sectional view along line I-I′ in FIG. 5, FIG. 7 illustrates a perspective view of the MOS transistor in FIG. 5, and FIG. 8 illustrates an enlarged cross-sectional view of portion “VIII” in FIG. 6.

Referring to FIGS. 5-7, a transistor, e.g., a MOS transistor, may include an active pattern 118 on a substrate 100, a gate structure 200 on the active pattern 118, and source/drain regions S/D adjacent to the gate structure 200. The substrate 100 may be any suitable semiconductor substrate, e.g., a substrate including single crystalline silicon.

The active pattern 118 may be irregularly shaped, and may include at least one protrusion extending in a vertical direction, e.g., along the y-axis, and having a gradually decreasing width along a horizontal direction, e.g., along the x-axis, in an upward vertical direction. In particular, as illustrated in FIG. 6, the protrusion of the active pattern 118 may have a lower surface on the substrate 100 and a sharp upper surface with a substantially narrow width opposite the lower surface. As illustrated in FIGS. 5 and 7, the protrusion may have a predetermined length along a first direction, e.g., along the z-axis, so a channel region of the transistor may be formed along the first direction in the protrusion.

In this example embodiment, the protrusion of the active pattern 118 may have a triangular prism shape. The lower surface of the protrusion may be positioned on an upper surface of the substrate 100, as illustrated in FIG. 6. Second and third surfaces of the protrusion may extend from the upper surface of the substrate 100 in an upward direction, and may connect to form an edge portion. Accordingly, the width, i.e., a distance as measured along a second direction, of the protrusion may gradually and continually decrease from the lower surface of the protrusion to the edge portion of the protrusion. Therefore, the edge portion of the protrusion may be substantially narrow along the second direction, e.g., along the x-axis, and may correspond to a first active region 118a, as further illustrated in FIG. 6. Accordingly, the first active region 118a may extend along the first direction, e.g., along the z-axis, and may be substantially narrow along a second direction, e.g., along the x-axis.

The edge portion of protrusion, i.e., the first active region 118a, may have any suitable sharp shape, i.e., a structure having a pointed tip with a substantially narrow width. For example, the edge portion of the protrusion may have a rounded shape, an angular shape, and so forth. For example, as illustrated in FIG. 8, the uppermost edge of the first active region 118a may be rounded, e.g., a rounded convex shape without a flat face, and may have a radius of curvature of about 1 nm to about 25 nm. Formation of the active pattern 118 with the first active region 118a may be advantageous in providing an active region with a sharp edge, so intensity of the electric field in the sharp edge of the active region may be substantially increased as described previously with reference to FIGS. 1-4.

Accordingly, when applying a substantially same voltage to the entire active pattern 118 of the transistor in FIGS. 5-7, a relatively large amount of charges may be discharged from the sharp edge of the active pattern 118, i.e., the first active region 118a, rather than from flat portions of the active pattern 118. Therefore, a relatively high electric field may be generated in the first active region 118a. Accordingly, when the channel region of the transistor is formed in the first active region 118a, the amount of charges discharged into the first active region 118a by the gate structure 200 may be greatly increased, thereby increasing an on-current. As a result, the transistor may have a fast operation speed.

The active pattern 118 may further include a second active region 118b. The second active region 118b may extend from both ends of the protrusion of the active pattern 118, as illustrated in FIGS. 5 and 7. In this example embodiment, a portion of the second active region 118b may extend from each end of the protrusion along the first direction, i.e., along the z-axis. The second active region 118b may have an irregular cross section in the xz-plane, as illustrated in FIG. 5, and may have a substantially wider upper surface than an upper surface of the protrusion along the second direction, e.g., along the x-axis. An upper surface of the second active region 118b may be substantially coplanar with the first active region 118a. In other words, the second active region 118b may be substantially level with an outermost edge of the protrusion.

Isolation layer patterns 124 may be formed in recesses adjacent to the active pattern 118. For example, as illustrated in FIGS. 5 and 7, the isolation layer patterns 124 may surround the active pattern 118, such that side surfaces of the active pattern 118 may be covered. The isolation layer patterns 124 may be on side surface of the protrusion, and may expose an uppermost edge of the protrusion, i.e., the first active region 118a. The isolation layer patterns 124 may include an insulation material, e.g., a silicon oxide.

As illustrated in FIGS. 5 and 7, the gate structure 200 may include a gate insulation layer 126 and a gate electrode 128. The gate insulation layer 126 may be formed on upper surfaces of the first active region 118a and on the isolation layer patterns 124. The gate insulation layer 126 may extend along the second direction, e.g., along the x-axis, and may have sufficient width along the first direction, e.g., along the z-axis, to overlap the length of the first active region 118a. For example, the gate insulation layer 126 and the first active region 118a may completely overlap each other, so the gate insulation layer 126 may completely overlap the channel in the protrusion of the active pattern 118. The gate insulation layer 126 may include, e.g., one or more of a silicon oxide, a metal oxide having a high dielectric constant, a nitride, and so forth.

As further illustrated in FIGS. 5 and 7, the gate electrode 128 may be formed on the gate insulation layer 126, so the gate insulation layer 126 may be between the gate electrode 128 and the first active region 118a. Accordingly, a lower surface of the gate electrode 128, i.e., a surface positioned on the gate insulation layer 126, may be higher than the first active region 118a along the y-axis relative to an upper surface of the substrate 100. The gate electrode 128 may overlap the gate insulation layer 126, and may extend along a direction substantially perpendicular to a direction of the first active region 118a, i.e., along the x-axis. The gate electrode 128 may include one or more of a metal, a semiconductor material doped with impurities, and so forth.

The source/drain regions S/D may be adjacent to the gate structure 200, as illustrated in FIG. 5. In particular, the source/drain regions S and D may be formed under the first active region 118a at both sides of the gate electrode 128. Further, an impurity region (not illustrated) may be formed under the second active region 118b, and may be connected to the source/drain regions S/D. A contact plug (not illustrated) may be formed on the second active region 118b, and may be connected to the impurity region and to the source/drain regions S/D.

A transistor structure according to embodiments of the present invention may be advantageous in providing an active region having a substantially sharp edge portion and a substantially narrow effective width along a lengthwise direction of the gate electrode, i.e., along the x-axis. Accordingly, the field enhancement factor β in the transistor may increase due to the sharp shape of the first active region 118a. Therefore, when voltage is applied to the gate electrode 128, the amount of charges discharged into the first active region 118a may be substantially increased. As a result, the channel region in the transistor may be rapidly formed and a drain current may be increased. Therefore, a transistor according to embodiments of the present invention may provide increased drain current and enhanced operation speed. Thus, although the gate insulation layer 126 may be slightly thicker than a gate insulation layer in a conventional transistor, the transistor according to embodiments of the present invention may exhibit a substantially improved performance as compared to the conventional transistor due to its increased drain current and enhanced operation speed. In addition, the transistor according to embodiments of the present invention may exhibit increased reliability and reduced leakage current through the gate insulation layer due to its thickness. Further, since most of the charges may be discharged by applying the voltage to the gate electrode 128, a short channel effect may not be generated regardless of a short length of the gate electrode 128. Also, since the gate electrode 128 may have a substantially narrow width, the transistor may have a high degree of integration.

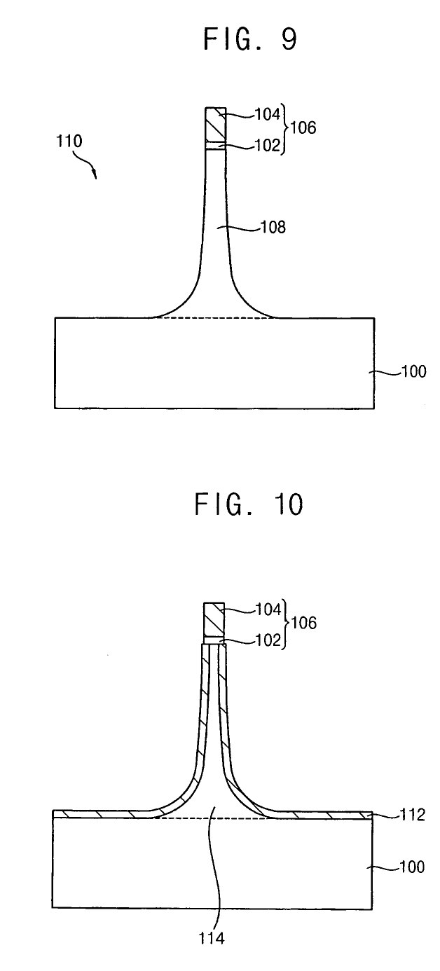

FIGS. 9-14 illustrate cross-sectional views of sequential stages in a method of manufacturing the transistor in FIGS. 5-8. It is noted that FIGS. 9-14 correspond to a cross-section of the transistor along line I-I′ in FIG. 5.

Referring to FIG. 9, a mask pattern 106 may be formed on the substrate 100. The mask pattern 106 may have a shape corresponding to a shape of the active region 118 of the MOS transistor, so the mask pattern 106 may cover an entire upper surface of a region to function as the active region 118 of the substrate 100. For example, since the first active region 118a may be narrower than the second active region 118b, a portion of the mask pattern 106 corresponding to the first active region 118a may be narrower than a portion of the mask pattern 106 corresponding to the second active region 118b. The mask pattern 106 may include a pad oxide layer pattern 102 and a silicon nitride layer pattern 104 on the pad oxide layer pattern 102.

The substrate 100 may be anisotropically etched using the mask pattern 106 as an etching mask to form a first preliminary active pattern 108. In particular, portions of the substrate 100 not covered by the mask 106 may be removed to form first preliminary recesses 110 to define side surfaces of the first preliminary active pattern 108. The first preliminary recesses 110 may be on both sides of the first preliminary active pattern 108, and may be formed so the first preliminary active pattern 108 may have a gradually decreasing width along the x-axis in a vertical direction, i.e., along the y-axis. During etching of the substrate 100, the mask pattern 106 may be partially removed by the anisotropic etching process, so thickness of the mask pattern 106 along the vertical direction, i.e., along the y-axis, may be reduced.

Referring to FIG. 10, side surfaces of the first preliminary active pattern 108 may be thermally oxidized to form a first sidewall oxide layer 112. In particular, thermal oxidation of side surfaces of the first preliminary active pattern 108 may trigger an oxidation reaction between the first preliminary active pattern 108 and an oxidizing agent to transform a predetermined thickness along outer side surfaces of the first preliminary active pattern 108 into the first sidewall oxide layer 112. Accordingly, a portion of the first preliminary active pattern 108 not reacted with the oxidizing agent may define a second preliminary active pattern 114 having a narrower width than the first preliminary active pattern 108 along the x-axis. As illustrated in FIG. 11, the first sidewall oxide layer 112 may be removed to expose the second preliminary active pattern 114. In other words, second preliminary recesses 116 may be formed to define side surfaces of the second preliminary active pattern 114. The second preliminary recesses 116 may be on both sides of the second preliminary active pattern 114, and may be wider than the first preliminary recesses 110, i.e., a distance as measured along the x-axis from an edge of the substrate 100 to an immediately adjacent outer surface of the second preliminary active pattern 114.

Referring to FIG. 12, side surfaces of the second preliminary active pattern 114 may be thermally oxidized to form a second sidewall oxide layer 120. Accordingly, a portion of the second preliminary active pattern 114 not oxidized with an oxidizing agent may define the active pattern 118. As illustrated in FIG. 12, the active pattern 118 may be narrower than the second preliminary active pattern 114 along the x-axis, and may have a sharp uppermost surface. The sharp uppermost surface of the active pattern 118 may be rounded. Recesses 122 may be formed at both sides of the active pattern 118. The active pattern 118 may include the first active region 118a and the second active region 118b (not shown) extending from both ends of the first active region 118a. The first active region 118a may protrude upwardly from the substrate 100, and may have a sharp uppermost surface. The second active region 118b may have a larger area than the first active region 118a.

It is noted that although not illustrated in the figures, the second sidewall oxide layer 120 may be removed and an additional oxide layer may be formed and removed in order to reduce width of the active pattern 118 and to sharpen the first active region 118a. Alternatively, the sidewall oxide layer, e.g., the second sidewall oxide layer 120, may not be removed, and may be used as a portion of the isolation layer pattern 124 formed in a subsequent process, as illustrated in FIG. 13.

Referring to FIG. 13, a silicon oxide layer (not shown) may be formed on the sidewall oxide layer 120 and on the substrate 100 to fill up the recesses 122 and to surround the active pattern 118. The silicon oxide layer may be planarized to expose the mask pattern 106, so the planarized silicon oxide layer may define the isolation layer pattern 124. The silicon oxide layer may be planarized by, e.g., a chemical mechanical polishing (CMP) process.

The mask pattern 106 may be partially removed during the CMP process. In particular, thickness of the mask pattern 106 on the active pattern 118 may be controlled to be substantially thin after performing the CMP process. Accordingly, when a remainder of the mask pattern 106 is removed to expose upper surfaces of the first and second active regions 118a and 118b, the upper surfaces of the first and the second active regions 118a and 118b may be substantially coplanar with an upper surface of the isolation layer pattern 124, as illustrated in FIG. 13.

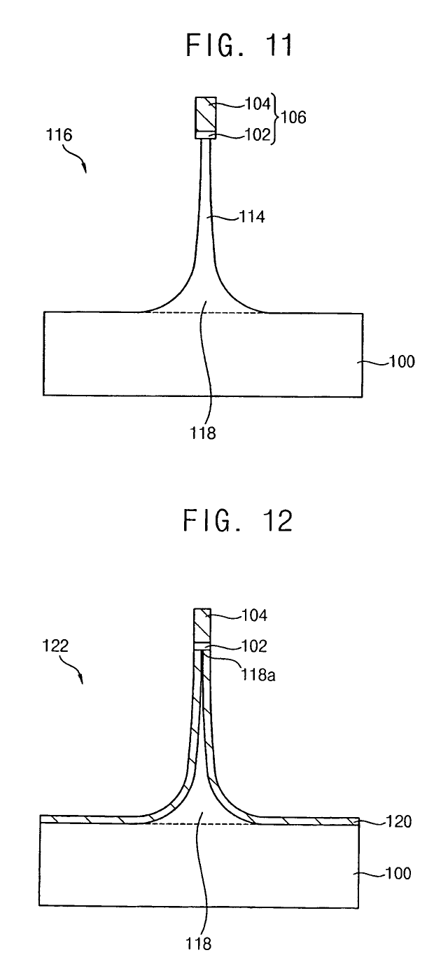

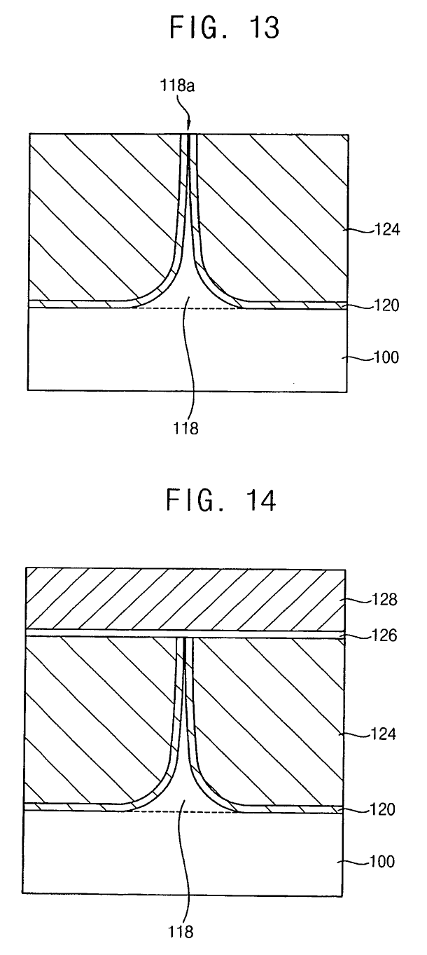

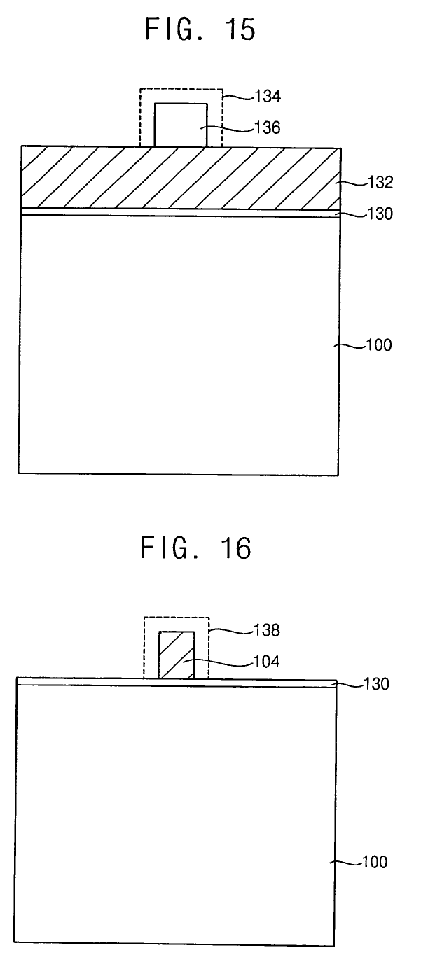

Referring to FIG. 14, the gate insulation layer 126 may be formed on the active pattern 118 and on the isolation layer pattern 124. The gate insulation layer 126 may include, e.g., one or more of a silicon oxide, a silicon nitride, a metal oxide having a dielectric constant higher than that of a silicon nitride, and so forth.

Next, a gate conductive layer (not illustrated) may be formed on the gate insulation layer 126. The gate conductive layer may include, e.g., one or more of polysilicon doped with impurities, a metal, a metal nitride, a metal silicide, and so forth. The gate conductive layer may be patterned to form the gate electrode 128, such that the gate electrode 128 may extend along a direction substantially perpendicular to a direction of the first active region 118a.

Alternatively, the gate insulation layer 126 and the gate electrode 128 may be formed by a damascene process. In particular, a mold pattern (not shown) may be formed on the active pattern 118 and on the isolation layer pattern 124. The mold pattern may have an opening for exposing a region for forming the gate insulation layer 126 and the gate electrode 128. For example, a silicon oxide layer may be deposited in the opening of the mold pattern to form the gate insulation layer 126, and the gate conductive layer may be formed on the gate insulation layer 126 to fill up the openings of the mold pattern. A CMP process may be performed on the gate conductive layer to expose an upper surface of the mold pattern, i.e., the upper surface of the mold pattern may be coplanar with an upper surface of the gate electrode 128, to from the gate electrode 128.

Impurities may be implanted into the substrate 100 under the first active region 118a and under the second active region 118b at both sides of the gate electrode 128 to form source/drain regions.

Alternatively, the transistor in FIGS. 5-8 may be formed according to another example embodiment illustrated in FIGS. 15-18. It is noted that the manufacturing method illustrated in FIGS. 15-18 may be substantially similar to the method described previously with reference to FIGS. 9-14, with the exception of a process for forming the active pattern 118.

Referring to FIG. 15, a pad oxide layer 130 and a silicon nitride layer 132 may be sequentially formed on the substrate 100. A photoresist film (not illustrated) may be formed on the silicon nitride layer 132. The photoresist film may be patterned by an exposure process, a development process, and a baking process to form a preliminary photoresist pattern 134. The preliminary photoresist pattern 134 may be partially ashed using oxygen plasma to form a photoresist pattern 136 having a narrower width than the preliminary photoresist pattern 134. The photoresist pattern 136 may be formed to cover the first active region 118a with the channel region and the second active region 118b. Since the first active region 118a may be narrower than the second active region 118b, a portion of the photoresist pattern 136 overlapping the first active region 118a may be narrower that a portion of the photoresist pattern 136 overlapping the second active region 118b.

Referring to FIG. 16, the silicon nitride layer 132 may be etched using the photoresist pattern 136 as an etching mask to form a preliminary silicon nitride layer pattern 138. The preliminary silicon nitride layer pattern 138 may be anisotropically etched to form a silicon nitride layer pattern 104 having a width narrower than the preliminary silicon nitride layer pattern 138. After forming the silicon nitride layer pattern 104, the photoresist pattern 136 may be removed by an ashing process and/or a stripping process. It is noted that both processes of ashing a photoresist pattern with plasma and anisotropically etching a mask pattern refer to processes of forming a mask having a narrower width. Thus, either one of the processes, i.e., ashing a photoresist pattern with plasma and anisotropically etching a mask pattern, may be omitted.

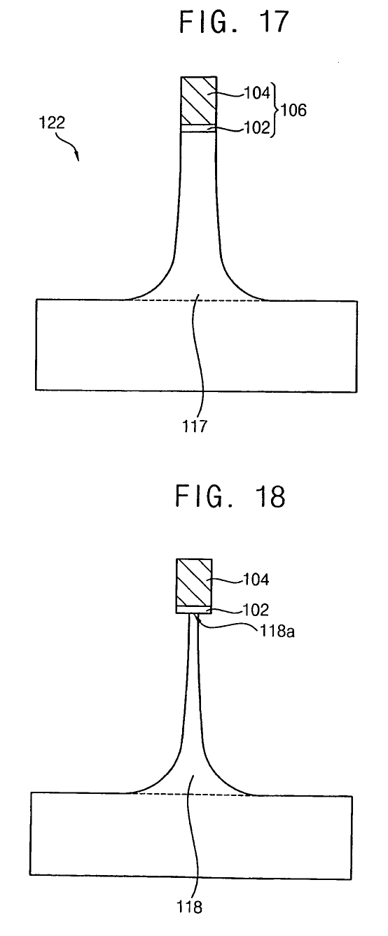

Referring to FIG. 17, the pad oxide layer 130 may be etched using the silicon nitride layer pattern 104 as an etching mask to form a pad oxide layer pattern 102, so the pad oxide layer pattern 102 and the silicon nitride layer pattern 104 may form the mask pattern 106 on the substrate 100, as described previously with reference to FIG. 9. The substrate 100 may be etched using the mask pattern 106 as an etching mask to form a preliminary active pattern 117. Further, recesses 122 may be formed at both sides of the preliminary active pattern 117. The preliminary active pattern 117 may have a gradually upwardly decreasing width. It is noted that a portion of the mask pattern 106 corresponding to a region to include the first active region 118a may have a substantially narrow width, so the first active region in the preliminary active pattern 117 may also have a substantially narrow width. Further, the first preliminary active pattern 117 may have a sharp uppermost surface.

Referring to FIG. 18, the preliminary active pattern 117 and the substrate 100 may be isotropically etched to form the active pattern 118 having a sharper uppermost surface than the first preliminary active pattern 117. In order to simplify the process for forming the active pattern 118, either one of the processes for isotropically etching the mask pattern 106 and the process for isotropically etching the preliminary active pattern 117 may be omitted. Processes substantially similar to the processes described previously with reference to FIGS. 13-14 may be performed to complete the transistor including the isolation layer pattern, the gate insulation layer, the gate electrode, and the source/drain regions.

According to another embodiment illustrated in FIG. 19, a transistor may be formed as follows. FIG. 19 illustrates a cross-sectional view of a transistor, e.g., a MOS transitory, in accordance with another example embodiment of the present invention. It is noted that the transistor illustrated in FIG. 19 may include elements substantially similar to the elements of the transistor described previously with reference to FIGS. 5-8, with the exception of a shape of the gate structure. Thus, same reference numerals refer to same elements throughout, and any detailed description thereof will not be repeated.

Referring to FIG. 19, the active pattern 118 may be formed on the substrate 100, as described previously with reference to FIGS. 5-8. The active pattern 118 may have a protrusion with a gradually upwardly decreasing width and with a sharp uppermost edge. The sharp uppermost edge may correspond to the first active region 118a of the active pattern 118. A portion of the active pattern 118 connected to the first active pattern 118a and having a greater width than the first active pattern 118a may correspond to the second active region 118b (not illustrated).

Isolation layer patterns 124′ may be formed in recesses between and around the active patterns 118, as illustrated in FIG. 19. As further illustrated in FIG. 19, upper surfaces of the isolation layer patterns 124′ may be vertically higher, i.e., along the y-axis, than the uppermost edge of the protrusion of the active pattern 118, i.e., the first active region 118a, relative to the upper surface of the substrate 100. Further, as illustrated in FIG. 19, the isolation layer patterns 124′ may have an opening 130 for exposing the first active region 118a. In other words, a bottom surface of the opening 130 may be vertically lower than the upper surface of the isolation layer patterns 124′.

A gate insulation layer 126′ may be formed conformally on the isolation layer patterns 124′, so the gate insulation layer 126′ may be disposed along inner surfaces of the opening 130 and on the first active region 118a exposed through the opening 130. Accordingly, the gate insulation layer 126′ may not be planar.

A gate electrode 128′ may be formed on the gate insulation layer 126′, and may extend along a direction substantially perpendicular to a direction of the first active region 118a. A portion of the gate electrode 128′ may be formed in the opening 130. Source/drain regions may be formed under the first active region 118a at both sides of the gate electrode 128.

A method of manufacturing the transistor of FIG. 19 may be substantially similar to the methods described previously with reference to FIGS. 9-18, with the exception of formation of the gate structure. As such, processes substantially similar to those described previously with reference to FIG. 9-12 or 15-18 may be performed to form the active pattern 118.

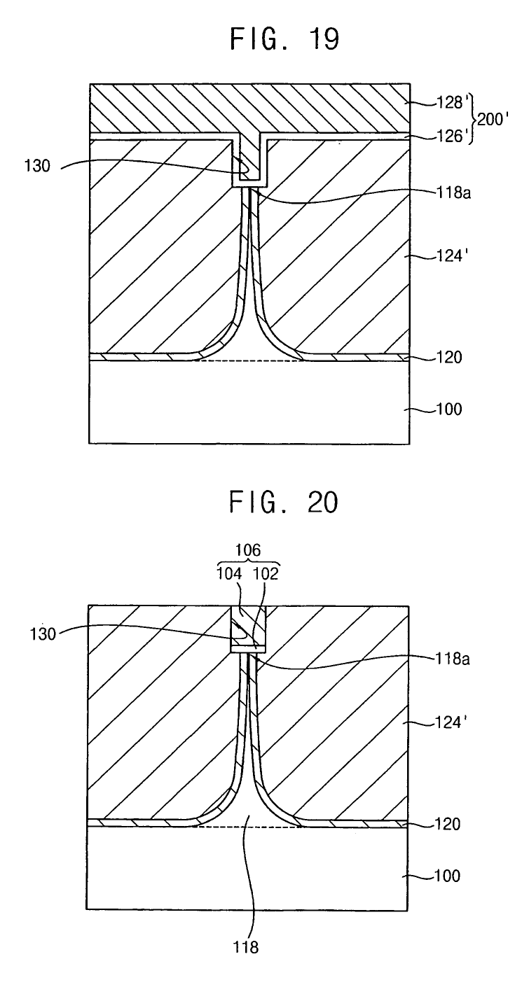

Next, referring to FIG. 20, a silicon oxide layer (not shown) may be formed on and around the active pattern 118. The silicon oxide layer may be planarized to expose an upper surface of the mask pattern 106, so the planarized silicon oxide layer may define the isolation layer pattern 124′. Upper surfaces of the mask pattern 106 and the isolation layer pattern 124′ may be substantially level. Accordingly, the silicon oxide layer may have sufficient thickness for covering the mask pattern 106.

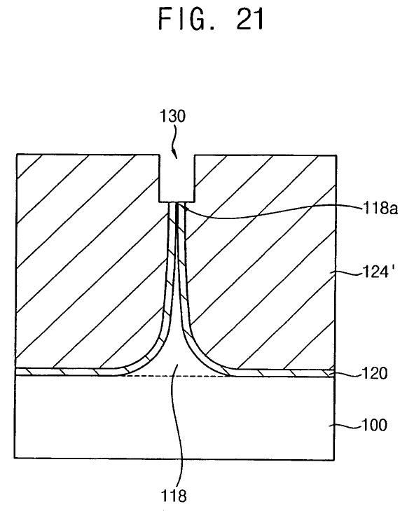

Referring to FIG. 21, the mask pattern 106 may be removed by a wet etching process to form the opening 130 exposing the first active region 118a and the second active region (not illustrated). Although not illustrated in the figures, processes substantially the same as those described previously with reference to FIGS. 13-14 may be performed to complete the gate structure of the transistor, i.e., form the gate insulation layer 126′ and the gate electrode 128′.

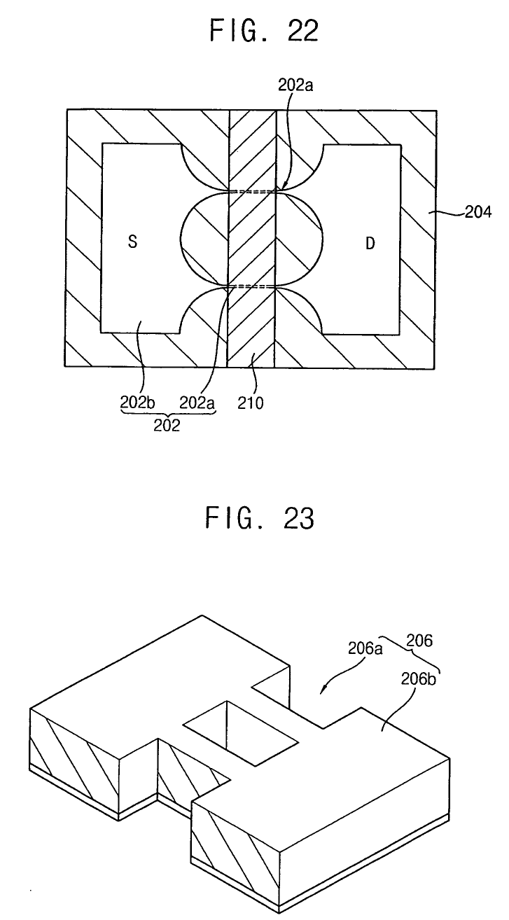

According to another embodiment illustrated in FIG. 22, a transistor may be formed as follows. FIG. 22 illustrates a plan view of a transistor, e.g., a MOS transistor, in accordance with another example embodiment of the present invention. It is noted that the transistor illustrated in FIG. 22 may include elements substantially similar to the elements of the transistor described previously with reference to FIGS. 5-8, with the exception of having a plurality of channel regions. Thus, any detailed description of the same elements will not be repeated.

Referring to FIG. 22, an active pattern 202 may be formed on the substrate 100 (not illustrated). The active pattern 202 may include a plurality of protrusions having gradually upwardly decreasing widths. Further, each of the protrusions may have a sharp uppermost surface. Each protrusion may be substantially similar to the protrusion of the active pattern 118 described previously with reference to FIGS. 5-8. The protrusions of the active pattern 202 may be parallel to each other, so triangular prism shapes thereof may be arranged in parallel with each other. For example, an uppermost edge of each protrusion may have a radius of curvature of about 1 nm to about 25 nm.

Each active pattern 202 may include a first active region 202a and a second active region 202b that may be substantially similar to the first and second active regions 118a and 118b, respectively, described previously with reference to FIGS. 5-8. The second active regions 202b may be connected between both ends of the protrusions, and may have upper surfaces substantially coplanar with the first active regions 202a. Upper surfaces of the second active regions 202b may be wider than upper surfaces of the first active regions 202a.

Since the transistor in FIG. 22 may include a plurality of protrusions, e.g., two protrusions, a channel region may be formed in each protrusion when the transistor is operated. Accordingly, a plurality of channel regions, e.g., two channel regions, may be formed parallel to each other in a single transistor. Thus, a plurality of current paths may be formed from the channel regions when the transistor is operated, thereby increasing drain current and operation speed of the transistor.

Isolation layer patterns 204 may be formed in recesses between the active patterns 202. The first active regions 202a and the second active regions 202b may be exposed by the isolation layer patterns 204.

A gate insulation layer (not shown) may be formed on the first active regions 202a and on the isolation layer patterns 204. A gate electrode 210 may be formed on the gate insulation layer. The gate electrode 210 may extend along a direction substantially perpendicular to a direction of the first active regions 202a. The gate electrode 210 may include, e.g., one or more of a metal, a semiconductor material doped with impurities, and so forth.

Source/drain regions may be formed under the first active regions 202a at both sides of the gate electrode 210. Further, an impurity region (not shown) may be formed under the second active regions 202b, and may be connected to the source/drain regions. A contact plug (not illustrated) may be formed on the second active region 202b, and may be connected to the impurity region and to the source/drain regions.

The transistor of FIG. 22 may be manufactured according to a method substantially similar to the methods described previously with reference to FIGS. 9-18, with the exception of a shape of a mask pattern used for patterning the active pattern 202. FIG. 23 illustrates a perspective view of a hard mask pattern for manufacturing the transistor in FIG. 22.

Referring to FIG. 23, a hard mask pattern 206 may be used to form the active pattern 202, so the first active regions 202a may be parallel with each other. The hard mask pattern 206 may include linear first portions 206a and second portions 206b. The hard mask pattern 206 may be formed on the substrate, so the linear first portions 206a may be arranged in parallel to correspond to a region where the first active regions 202a are to be formed. Each of the linear first portions 206a may have a first width. The second portions 206b may have a second width greater than the first width, and may be connected to both ends of the linear first portions 206a. The second portions 206b may be arranged to correspond to a region where the second active regions are to be formed. Thus, the transistor of FIG. 22 may be manufactured by performing the methods described previously with reference to FIG. 9-18, with the exception of using the hard mask pattern 206 of FIG. 23, instead of the pattern mask 106 of FIGS. 9-18.

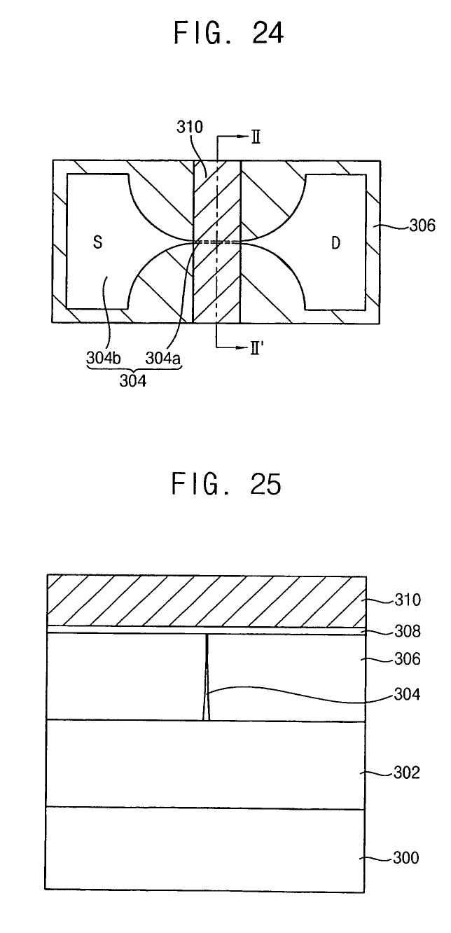

According to another embodiment of the present invention illustrated in FIGS. 24-25, a transistor may be substantially similar to the transistor of FIGS. 5-9, with the exception of using a silicon-on-insulator (SOI) substrate. Thus, any detailed description of similar elements of the transistor will not be repeated. FIG. 24 illustrates a planar view of the transistor, e.g., a MOS transistor, in accordance with another embodiment of the present invention, and FIG. 25 illustrates a cross-sectional view along line II-II′ in FIG. 24.

Referring to FIGS. 24-25, an insulation layer 302 may be formed on a lower substrate 300 including single crystalline silicon. An active pattern 304 may be formed on the insulation layer 302 including single crystalline silicon. The active pattern 304 may include at least one protrusion having a gradually upwardly decreasing width, so the protrusion may have a sharp uppermost surface. The sharp uppermost surface of the protrusion may correspond to a first active region 304a. A channel region of the transistor may be formed in the first active region 304a. The active pattern 304 may include a second active region 304b substantially similar to the second active region 118b described previously with reference to FIGS. 5-9, and therefore, its detailed description will not be repeated.

Isolation layer patterns 306 may be formed in a recess between the active patterns 304, a gate insulation layer (not shown) may be formed on the first active region 304a and on the isolation layer patterns 306, a gate electrode 310 may be formed on the gate insulation layer, and source/drain regions may be formed under the first active region 304a. The isolation layer patterns 306, gate insulation layer, gate electrode 310, and source drain regions may be substantially similar to the isolation layer patterns 124, gate insulation layer 126, gate electrode 128, and source/drain regions S/D, respectively, described previously with reference to FIGS. 5-9, and therefore, their detailed description will not be repeated.

A method of manufacturing the transistor of FIGS. 24-25 may be substantially similar to the methods described previously with reference to FIGS. 9-18, with the exception of using the SOI substrate. Thus, any further descriptions with respect to the method may be omitted. It is noted, however, that formation of the transistor of FIGS. 24-25 may include exposing the insulation layer 302 through the recesses when the single crystalline silicon layer on the insulation layer 302 is etched to form the recesses. It is further noted that the formation of the transistor of FIGS. 24-25 may not include removing the sidewall oxide layer after forming the sidewall oxide layer, because the insulation layer 302 under the sidewall oxide layer may be partially removed together with the sidewall oxide layer.

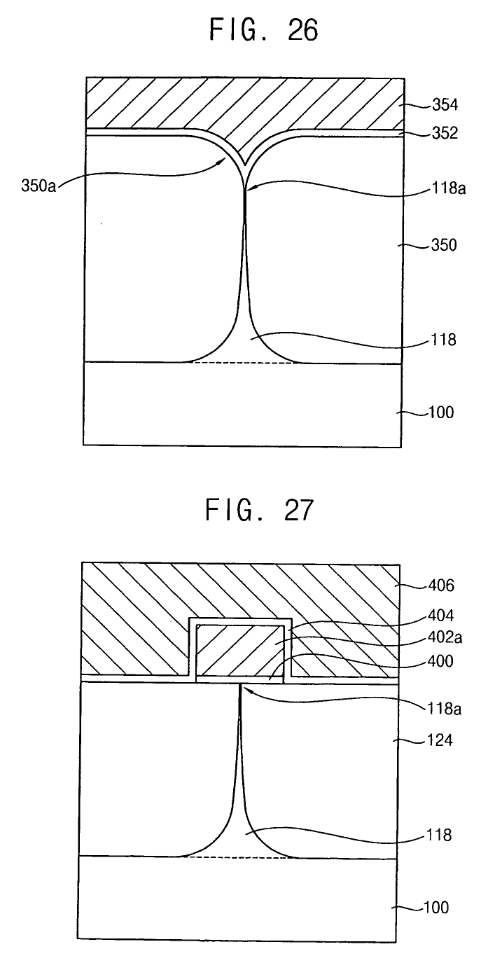

According to another embodiment of the present invention illustrated in FIG. 26, a transistor may be substantially similar to the transistor of FIGS. 5-9, with the exception of the gate structure shape. Thus, any detailed description of similar elements of the transistor will not be repeated. FIG. 26 illustrates a cross-sectional view of the transistor, e.g., a MOS transistor, in accordance with another example embodiment of the present invention.

Referring to FIG. 26, the transistor may include the active pattern 118 on the substrate 100 as described previously with reference to FIGS. 5-9. Isolation layer patterns 350 may be formed in recesses between the active patterns 118. The first active regions 118a may be exposed by the isolation layer patterns 350.

The isolation layer patterns 350 may have an uneven upper surface, so a portion of the isolation layer patterns 350 above the first active region 118a may be curved, as illustrated in FIG. 26. In this example embodiment, the upper surface of the isolation layer pattern 350 may be vertically higher than the first active region 118a, so each of the isolation layer patterns 350 may include a first upper surface portion and a second upper surface portion. The first upper surface portion of the isolation layer patterns 350 may be substantially flat, and may be positioned in parallel with the substrate 100. The first upper surface portion of the isolation layer patterns 350 may not overlap the first active region 118a. The second upper surface portion of the isolation layer patterns 350 may be curved, and may extend from the first upper surface portion in a downward direction toward the first active region 118a. Accordingly, second upper surface portions of isolation layer patterns 350 deposited in recesses adjacent to both sides of the protrusion of the active pattern 118 may expose the first active region 118a therebetween.

Since the second upper surface portions of the isolation layer patterns 350 are curved, a recess 350a may be formed therebetween. The recess 350a may have a gradually downwardly decreased width, so the recess 350a may have a sharp lowermost edge. The recess 350a may be above the first active region 118a, as illustrated in FIG. 26. A gate insulation layer 352 may be formed conformally on the active pattern 118 and on the isolation layer patterns 350, so a portion of the gate insulation layer 352 may be deposited in the recess 350a.

A gate electrode 354 may be formed conformally on the gate insulation layer 352. The gate electrode 354 may extend along a direction substantially perpendicular to a direction of the first active region 118a. The gate electrode 354 may include one or more of a metal, a semiconductor material doped with impurities, and so forth.

Since the gate electrode 354 may be formed conformally on the gate insulation layer 352, the gate electrode 354 may have a bottom portion corresponding to the recess 350a, i.e., substantially similar to the second portions of the upper surface of the isolation layer patterns 350. In other words, the bottom surface of the gate electrode 354 may be uneven because the bottom portion of the gate electrode 354 in the recess 350a may have a sharp shape. In particular, the bottom portion of the gate electrode 354 in the recess 350a may have a gradually upwardly increasing width. The sharp portion of the gate electrode 354 may be symmetrical with the first active region 118a. Thus, a relatively large amount of charges may be discharged in the channel region due to the shape characteristics of the gate electrode 254, so that the transistor may have improved operational characteristics.

Source/drain regions may be formed under the first active region 118a at both sides of the gate electrode 354. Further, an impurity region (not illustrated) may be formed under the second active region, and may be connected to the source/drain regions. A contact plug (not illustrated) may be formed on the second active region, and may be connected to the impurity region and to the source/drain regions.

A method of manufacturing the transistor of FIG. 26 may be substantially similar to the methods described previously with reference to FIGS. 9-18, with the exception of a process for forming the gate electrode.

In particular, the active pattern 118 may be formed by a substantially same method described previously with reference to FIGS. 9-12 or FIGS. 15-18. Next, a silicon oxide layer (not shown) may be formed on the active pattern 118 to fill up the recess at both sides of the active pattern 118 and to cover the active pattern 118. The silicon oxide layer may be planarized by the CMP process.

A portion of the silicon oxide layer directly above the first active region 118a, i.e., a portion facing the first active region 118a, may be anisotropically etched to form a preliminary opening having an inclined side surface. The silicon oxide layer exposed through the preliminary opening may be isotropically etched until the first active region 118a is exposed to form the recess 350a having the curved surfaces forming a sharp bottom face oriented toward the first active region 118a, i.e., a narrow tip of the sharp structure may be facing the first active region 119a. The gate insulation layer 352 and the gate electrode 354 may be formed on the isolation layer pattern 350 using a substantially same method described previously with reference to, e.g., FIG. 19, and therefore, their detailed description will not be repeated.

According to another embodiment of the present invention, a cell transistor of a non-volatile memory device may be formed as illustrated in FIG. 27. Referring to FIG. 27, the cell transistor may include the active pattern 118 and the isolation layer patterns 124 on the substrate 100 as described previously with reference to FIGS. 5-9. A tunnel oxide layer 400, e.g., a silicon oxide layer, may be formed on the first active region 118a and on the isolation layer patterns 124 to overlap the first active region 118a.

As illustrated in FIG. 27, a charge storage layer pattern 402a may be formed on the tunnel oxide layer 400 to overlap the first active region 118a. A lower surface of the charge storage layer pattern 402a may be vertically higher than the upper surface of the first active region 118a.

The charge storage layer pattern 402a may include, e.g., polysilicon doped with impurities. Alternatively, the charge storage layer pattern 402a may include, e.g., one or more of a silicon nitride, a nanocrystal, a silicon carbon, a metal oxide having a high dielectric constant, and so forth. If the charge storage layer pattern 402a includes polysilicon doped with impurities, the cell transistor may correspond to a charge floating type non-volatile memory device. In contrast, if the charge storage layer pattern 402a includes a silicon nitride, a nanocrystal, a silicon carbon, and/or a metal oxide having with a high dielectric constant, the cell transistor may correspond to a charge trapping type non-volatile memory device.

As further illustrated in FIG. 27, the charge storage layer pattern 402a may have substantially flat upper and lower surfaces. Alternatively, although not illustrated in the figures, the lower surface of the charge storage layer pattern 402a, i.e., a surface in direct contact with the tunnel oxide layer 400 and over the first active region 118a, may have a sharp shape oriented toward the first active region 118a. In this case, the sharp lower surface of the charge storage layer pattern 402a may store a relatively large amount of charges as compared to a flat lower surface of the charge storage layer pattern 402a.

A dielectric layer pattern 404 may be formed on the first active region 118a and on the isolation layer patterns 124. In particular, first portions of the dielectric layer pattern 404 may be directly on the isolation layer patterns 124, as illustrated in FIG. 27, and second portions of the dielectric layer pattern 404 may be formed on upper and side surfaces of the charge storage layer pattern 402a and on side surfaces of the tunnel oxide layer 400. The dielectric layer pattern 404 may include, e.g., one or more of a silicon oxide, a silicon nitride, a metal oxide having a high dielectric constant, and so forth.

A control gate pattern 406 may be formed on the dielectric layer pattern 404, e.g., on an entire upper surface of the dielectric layer pattern 404. The control gate pattern 406 may extend along a direction perpendicular to a direction of the first active region 118a. The control gate pattern 406 may include, e.g., one or more of a metal, a semiconductor material doped with impurities, and so forth.

Source/drain regions may be formed under the first active region 118a at both sides of the charge storage layer pattern 402a. An impurity region (not illustrated) may be formed under the second active region, and may be connected to the source/drain regions. A contact plug (not illustrated) may be formed on the second active region, and may be connected to the impurity region and to the source/drain regions.

The transistor cell may include a channel region in the protrusion of the active pattern 118. The field enhancement factor β may be substantially increased in the cell transistor of FIG. 27 due to the sharp shape of the first active region 118a. Thus, when a programming voltage is applied to the control gate pattern 406 of the cell transistor, an amount of the charges discharged into the first active region 118a may be increased. Further, a tunneling amount of the charges toward the charge storage layer pattern 402a may be increased. As a result, the cell transistor may have improved programming characteristics.

Further, when a reading voltage is applied to the control gate pattern 406, an amount of the charges discharged from the first active region 118a may be increased. Therefore, although a thickness of the tunnel oxide layer 400 may be relatively thick as compared to a tunnel oxide layer in a conventional cell transistor having a flat channel region, the cell transistor according to embodiments of the present invention may have improved on-current characteristics and operational properties. Further, the thickness of the tunnel oxide layer 400 may reduce a leakage current through the tunnel oxide layer 400 so that the cell transistor may have improved reliability.

It is noted that alternatively, although not illustrated in the drawings, a cell transistor of a non-volatile memory device may include the tunnel oxide layer 400, the charge storage layer pattern 402a, the dielectric layer pattern 404, and the control gate pattern 406 sequentially formed on the active pattern 118 as described previously with reference to FIGS. 19, 22, and 24.

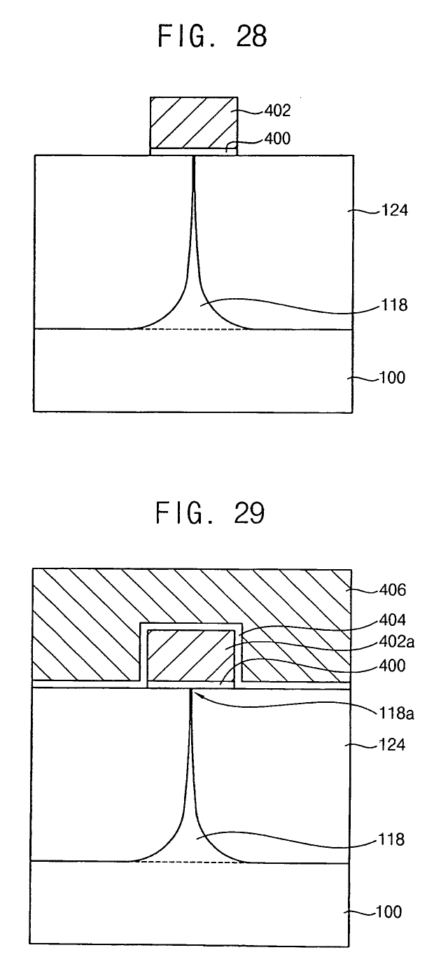

A method of manufacturing the cell transistor of FIG. 27 will be described in more detail with reference to FIGS. 28-29. The method of manufacturing the non-volatile memory device in FIG. 27 may include substantially same processes as described previously with reference to FIGS. 9-18, with the exception of a process for forming gate structures.

The active pattern 118 may be formed according to processes described previously with reference to FIGS. 9-2 or FIGS. 15-18. Referring to FIG. 28, the tunnel oxide layer 400 may be formed on the active pattern 118 and on the isolation layer patterns 124 by, e.g., depositing a silicon oxide layer. A charge storage layer (not illustrated) may be formed on the tunnel oxide layer 400 by, e.g., a chemical vapor deposition (CVD) process using polysilicon doped with impurities or by a CVD process using a silicon nitride. The charge storage layer may be anisotropically etched to form a preliminary charge storage layer pattern 402 extending along a direction substantially parallel to a direction of the first active region 118a.

Referring to FIG. 29, a dielectric layer (not illustrated) and a control gate conductive layer (not illustrated) may be sequentially formed on the preliminary charge storage layer pattern 402. The control gate conductive layer, the dielectric layer, and the preliminary charge storage layer pattern 402 may be patterned to form the charge storage layer pattern 402a, the dielectric layer pattern 404, and the control gate pattern 406, respectively. The control gate pattern 406 may extend along a direction substantially perpendicular to a direction of the first active region 118a.

Impurities may be implanted into the substrate 100 under the first active region 118a and under the second active region at both sides of the control gate pattern 406 to form source/drain regions, thereby completing the non-volatile memory device of this example embodiment.

Alternatively, although not illustrated in the drawings, the method of manufacturing the cell transistor of the non-volatile memory device may include sequentially forming the tunnel oxide layer, the charge storage layer pattern, the dielectric layer pattern, and the control gate pattern on an active pattern in substantially same methods used to form the transistors of FIGS. 19 and 22.

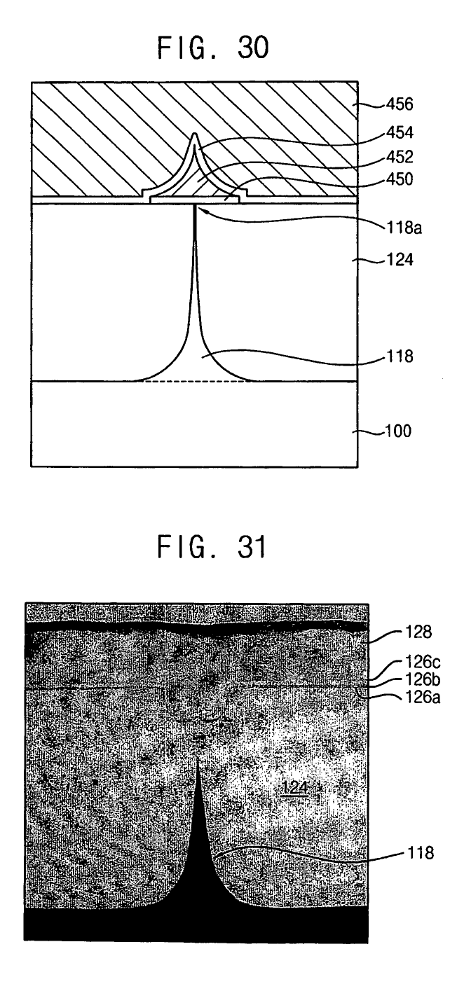

According to another embodiment of the present invention, a cell transistor of a non-volatile memory device will be described with reference to FIG. 30. Referring to FIG. 30, the cell transistor may include the active pattern 118 and the isolation layer patterns 124 on the substrate 100, as described previously with reference to FIGS. 5-9. A tunnel oxide layer 450, e.g., a silicon oxide layer, may be formed on the first active region 118a and on the isolation layer patterns 124 to overlap the first active region 118a.

As illustrated in FIG. 30, a charge storage layer pattern 452 may be formed on the tunnel oxide layer 450 to overlap the first active region 118a. The charge storage layer pattern 452 may include, e.g., polysilicon doped with impurities. Alternatively, the charge storage layer pattern 452 may include, e.g., one or more of a silicon nitride, a nanocrystal, a silicon carbon, a metal oxide having a high dielectric constant, and so forth.

The charge storage layer pattern 452, as further illustrated in FIG. 30, may have a sharp upper surface oriented away from the first active region 118a. In particular, a lower surface of the charge storage layer pattern 452 may be substantially flat, and may be positioned directly on the tunnel oxide layer 450. Side surfaces, e.g., opposing side surfaces, of the charge storage layer pattern 452 may extend from the lower surface of the charge storage layer pattern 452 in an upward direction to connect and to form a sharp edge oriented away from the first active region 118a. Thus, an amount of charges concentrated in the sharp edge of the charge storage layer pattern 452 may be increased as compared to a flat upper surface of a charge storage layer. As a result, the non-volatile memory device may have improved programming and erasing characteristics. Further, a coupling ratio of the non-volatile memory device may be readily controlled.

A dielectric layer pattern 454 may be formed conformally on the charge storage layer pattern 452 and on the isolation layer patterns 124. A control gate pattern 456 may be formed on the dielectric layer pattern 454. The control gate pattern 456 may extend along a direction perpendicular to a direction of the first active region 118a. Source/drain regions may be formed under the first active region 118a at both sides of the charge storage layer pattern 452.

Alternatively, although not illustrated in the drawings, the charge storage layer pattern may have a sharp lower surface oriented n a downward direction toward the first active region 118a and the control gate pattern 450. In this case, the non-volatile memory device may also have improved programming and erasing characteristics. Further, a coupling ratio of the non-volatile memory device may be readily controlled. It is further noted that, although not illustrated in the drawings, a cell transistor of a non-volatile memory device may include the tunnel oxide layer, the charge storage layer pattern, the dielectric layer pattern, and the control gate pattern sequentially formed on an active pattern as described previously with reference to FIGS. 19, 22, and 24.

### EXAMPLES

### Example 1

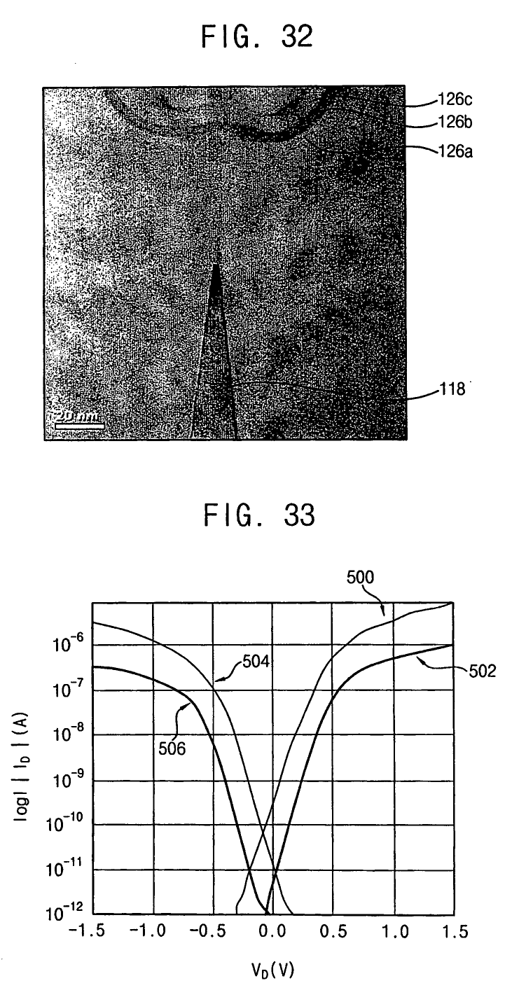

A MOS transistor was manufactured according to FIGS. 19-21, and a cross-section thereof was photographed. FIG. 31 illustrates a scanning electron microscope (SEM) photograph of the manufactured MOS transistor, and FIG. 32 illustrates an enlarged SEM photograph of an active pattern in the MOS transistor in FIG. 31. In FIGS. 31-32, reference numerals 118 and 124 indicate an active pattern and an isolation layer pattern, respectively. Further, reference numerals 126a, 126b, and 126c indicate a first silicon oxide layer, a silicon nitride layer, and a second silicon oxide layer, respectively. The stacked structure of oxide layers represents a gate insulation layer. As illustrated in FIG. 32, the active pattern 118 had an upper width of about no more than 5 nm. Further, the active pattern 118 extended under a lower surface of the gate insulation layer.

### Example 2

An n-type MOS (NMOS) transistor was manufactured according to FIGS. 19-21. In the NMOS transistor, a gate insulation layer included sequentially stacked a first silicon oxide layer having a thickness of 30 angstroms, a silicon nitride layer having a thickness of 48 angstroms, and a second silicon oxide layer having a thickness of 53 angstroms. Further, the gate insulation layer of the NMOS transistor had an equivalent oxide thickness (EOT) of 107 angstroms. A gate length was 60 nm and a first active region had a width of no more than 5 nm. N-type impurities were doped in a channel region and in source/drain regions of the NMOS transistor.

### Example 3

A p-type MOS (PMOS) transistor was manufactured in a substantially same method as the NMOS in Example 2, with the exception of having a gate insulation layer with a gate length of 70 nm and including p-type impurities.

Drain currents by gate voltages in the NMOS transistor and the PMOS transistor were measured. Measured results are illustrated in a graphical form in FIG. 33. In FIG. 33, the horizontal axis represents the gate voltage and the vertical axis represents the drain current.

Referring to FIG. 33, curves 500 and 502 represent the drain voltages measured in the NMOS transistor when the gate voltages were (−1) V and (−0.01) V, respectively. Further, curves 504 and 506 represent the drain voltages measured in the PMOS transistor when the gate voltages were (−1 ) V and (−0.01) V, respectively. Measured threshold voltages of the NMOS transistor and the PMOS transistor were 0.4 V and (−0.55) V, respectively. Further, measured saturated drain currents of the NMOS transistor and the PMOS transistor were 5.2 μA and (−2.5) μA, respectively. Thus, it can be noted that the saturated drain currents were very high with respect to the substantially narrow widths of the first active regions and the thicknesses of the gate insulation layers.

According to embodiments of the present invention, an electric field may be intensified in a channel region of a transistor, so that an amount of charges discharged in the channel region may be increased. Thus, a semiconductor device may have a fast response time and an increased drain current. Further, although a gate insulation layer may have a relatively high thickness, the semiconductor device may have a sufficient drain current. As a result, a leakage current through the gate insulation layer may be decreased by increasing thickness of the gate insulation layer, so that the semiconductor device may have improved reliability.

Exemplary embodiments of the present invention have been disclosed herein, and although specific terms may be employed, they may be used and may be to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A semiconductor device, comprising:
an active pattern on a substrate, the active pattern including a protrusion with a lower surface on the substrate and an upper surface opposite the lower surface, a width of the protrusion gradually decreasing from the lower surface to the upper surface, the upper surface of the protrusion being sharp and defining a first active region of the active pattern along a first direction;
isolation layer patterns on the substrate in recesses at both sides of the active pattern, the isolation layer patterns exposing the first active region;
a gate structure on the first active region and on the isolation layer patterns, the gate structure extending along a second direction, the first and second directions being perpendicular to each other; and
source/drain regions under the first active region at both sides of the gate structure.

2. The semiconductor device as claimed in claim 1, wherein the protrusion of the active pattern has a triangular prism shape.

3. The semiconductor device as claimed in claim 1, wherein the upper surface of the protrusion is rounded.

4. The semiconductor device as claimed in claim 3, wherein the upper surface of the protrusion has a radius of curvature of about 1 nm to about 25 nm.

5. The semiconductor device as claimed in claim 1, wherein the active pattern further comprises a second active region extending from both sides of the protrusion, the second active region having an upper surface substantially coplanar with an upper surface of the first active region and an upper width greater than an upper width of the first active region.

6. The semiconductor device as claimed in claim 5, wherein the active pattern includes a plurality of protrusions parallel to each other, each protrusion including a first active region, and both ends of each first active region being connected to the second active region.

7. The semiconductor device as claimed in claim 1, wherein the gate structure includes a gate insulation layer and a gate electrode on the gate insulation layer.

8. The semiconductor device as claimed in claim 7, wherein a lower surface of the gate electrode over the first active region has a sharp shape oriented toward the first active region.

9. The semiconductor device as claimed in claim 8, wherein the lower surface of the gate electrode is vertically higher than the first active region relative to the substrate.

10. The semiconductor device as claimed in claim 1, wherein the gate structure includes a tunnel oxide layer, a charge storage layer pattern on the tunnel oxide layer, a dielectric layer pattern on the charge storage layer pattern, and a control gate pattern on the dielectric layer pattern.

11. The semiconductor device as claimed in claim 10, wherein the charge storage layer pattern includes polysilicon doped with impurities.

12. The semiconductor device as claimed in claim 10, wherein the charge storage layer pattern includes one or more of a silicon nitride, a nanocrystal, a silicon carbon, and a metal oxide having a high dielectric constant.

13. The semiconductor device as claimed in claim 10, wherein a lower surface of the charge storage layer pattern over the first active region has a sharp shape oriented toward the first active region.

14. The semiconductor device as claimed in claim 10, wherein an upper surface of the charge storage layer pattern has a sharp shape oriented toward the control gate pattern.

15. The semiconductor device as claimed in claim 14, wherein a lower surface of the charge storage layer pattern has a sharp shape oriented toward the first active region.

16. The semiconductor device as claimed in claim 11, wherein the dielectric layer pattern includes one or more of a silicon oxide, a silicon nitride, and a metal oxide having a high dielectric constant.

17. A method of manufacturing a semiconductor device, comprising:
forming an active pattern on a substrate, the active pattern including a protrusion with a lower surface on the substrate and an upper surface opposite the lower surface, a width of the protrusion gradually decreasing from the lower surface to the upper surface, the upper surface of the protrusion being sharp and defining a first active region of the active pattern along a first direction;
forming isolation layer patterns on the substrate in recesses at both sides of the active pattern, the isolation layer patterns exposing the first active region;
forming a gate structure on the first active region and on the isolation layer patterns, the gate structure extending along a second direction, the first and second directions being perpendicular to each other; and
forming source/drain regions under the first active region at both sides of the gate structure.

18. The method as claimed in claim 17, wherein forming the upper surface of the protrusion includes forming a rounded upper surface.

19. The method as claimed in claim 17, wherein forming the active pattern includes,
forming a hard mask pattern on the substrate;
anisotropically etching the substrate using the hard mask pattern as an etching mask to form a preliminary protrusion with inclined side surfaces; and
partially removing the inclined side surfaces of the preliminary protrusion to form a sharp upper surface in the protrusion of the active pattern.

20. The method as claimed in claim 19, wherein partially removing the inclined side surfaces of the preliminary protrusion includes,
i) thermally oxidizing the side surfaces of the preliminary protrusion to form an oxide layer on the side surfaces of the preliminary protrusion;
ii) removing the oxide layer; and
iii) repeating i) and ii) at least once.

21. The method as claimed in claim 19, wherein the side surfaces of the preliminary protrusion are removed by a wet etching process.

22. The method as claimed in claim 17, wherein forming the hard mask pattern includes forming a mask having a first portion with a first width corresponding to the first active region and having a second portion with a second width corresponding to a second active region of the active pattern, the first portion of the hard mask pattern being connected to both ends of the first portion of the hard mask pattern, and the second width being greater than the first width.
